(19) United States
(12) Patent Application Publication
(10) Pub. No.: US 2002/0005526 A1
(43) Pub. Date: Jan. 17, 2002

(54) Electrostatic discharge protective structure and a method for producing it

(76) Inventors: Martin Czech, Freiburg (DE); Juergen Kessel, Freiburg (DE); Eckart Wagner, Vorstetten (DE)

Correspondence Address: Samuels, Gauthier & Stevens LLP, Suite 3300, 225 Franklin Street, Boston, MA, 02110, US

(21) Appl. No.: 09/852,122

(22) Filed: May 8, 2001

(30) Foreign Application Priority Data
May 8, 2000 (DE) 100 22 367.2

(51) Int. Cl. H01L 29/74

(52) U.S. Cl. 257/173; 257/360

(57) ABSTRACT

An electrostatic discharge (ESD) protective structure is configured and arranged to protect an integrated semiconductor circuit that is located between a first potential bus with a first supply potential and a second potential bus with a second supply potential. The ESD protective structure includes a laterally shaped ESD diode having a first region with a first conduction type and a second region of a second conduction type spaced apart from the first region. The ESD protective structure is located between the potential busses and is provided with a gate electrode, such that the first region and the second region are adjusted with respect to the gate electrode, and the spacing between the first region and the second region corresponds to the length of the gate electrode.

### BACKGROUND OF THE INVENTION

The invention relates to the field of semiconductor devices, and in particular to an electrostatic discharge (ESD) protective structure to protect an integrated semiconductor circuit against electric discharge.

During the operation of integrated circuits undesirably high voltage peaks may occur, which are coupled into the integrated circuit through the supply lines. Without suitable protective measures, parasitic overvoltages of a few volts and the electrostatic discharges caused thereby can damage and even destroy the integrated circuit. This makes the failure rate of such an integrated circuit unacceptably high.

To reduce their failure rate, circuits located on an integrated circuit often contain co-integrated ESD protective structures. These ESD protective structures can be inserted as clamping circuits between the supply lines of the integrated circuit and, in case of an electrostatic discharge, drain off the parasitic overvoltage to one of the supply lines. As a result, the parasitic overvoltage between the supply lines is reduced to a tolerable value (i.e., to a value that does not damage the integrated circuit).

An important boundary condition in the production of ESD protective structures derives from the requirement that under operational conditions (as these are described for example in the product specification) the ESD protective structures must not impair the function of the integrated semiconductor circuit that is being protected (or impair it only insignificantly). Thus the breakdown or switch-through voltage of the ESD protective element must be beyond nominal the signal voltage range of the circuit being protected. As a result, the ESD protective element should break down before the critical circuit path, but beyond the signal voltage range. As a rule this requires an exact adjustment of the breakdown and switch-through voltage of the particular ESD protective element.

ESD protective elements often include semiconductor components that are blocking at least part of the time, such as, for example, thyristors, bipolar transistors, field effect transistors, or diodes.

When thyristors or transistors are used, fast noise voltage pulses may cause these devices to switch on or fire inappropriately, even though their switch-on or firing voltage, as determined by characteristic measurements in the low-current region, lies outside the specified signal voltage range. This so-called transient latch-up, which may last an arbitrarily long time, causes a short circuit of the operating voltage and, as a rule, destroys the ESD protective element. As a result, the function of the integrated circuit is no longer assured. In the extreme case, the integrated circuit and even its voltage supply can be irreversibly damaged from strong heating (of the integrated circuit). Due to their transient latch-up, ESD protective elements that have a decided snap-back behavior, for example thyristors or bipolar transistors, are not well suited as ESD protective elements, despite their high ESD strength and good protective action.

ESD diodes, which up to now have been used for integrated semiconductor circuits, do not share these problems. Such a generic ESD diode is described in the DE 41 35 522 A1.

However, a problem with using pn diodes as ESD protection is that pn diodes cannot be integrated or can be integrated only with great expense in standard CMOS or MOS processes, since they are generally present as parasitic structures in CMOS or MOS processes. When such pn diodes are produced for ESD protection the process parameters must be tightly controlled, since in principle these are parasitic pn structures in a CMOS process. In addition, prior art pn diodes have an inadequate clamping action that can only be overcome by using special masks, epitaxial wafers, etc. Finally, parasitic surface charges result in leakage currents that cause a walk-out effect or diode leakage current, especially at high voltages. In addition, prior art pn diodes have a poor blocking characteristic (i.e., an undefined blocking characteristic) so that pn diodes as ESD protection suffer from considerable reliability problems.

Therefore, there is a need for an improved and easily manufactured ESD protective structure.

### SUMMARY OF THE INVENTION

Briefly, according to an aspect of the present invention, an ESD protective structure includes a laterally shaped ESD diode having a first region doped with a first conduction type and a second region doped with a second conduction type spaced apart from the first region. The ESD protective structure is located between first and second voltage potentials and the structure includes a gate electrode, such that the first region and the second region are adjusted with respect to the gate electrode, and the spacing between the first region and the second region corresponds to the length of the gate electrode.

The ESD diode preferably has a relatively simple structure that is easily manufactured, since the layout of a known MOS transistor is employed wherein the conductivity type is exchanged at the source region or the drain region.

Since the inventive ESD protective structure is preferably configured as a pn diode, problems with permanent short circuits which, for example, damage the voltage supply or the integrated circuit, are eliminated. The ESD diode adequately limits the voltage such that the integrated circuit is not damaged. Therefore, the ESD diode is especially suitable for high voltage applications.

Significantly, the ESD diode requires no special process steps or additional masks. In addition, since the ESD diode is derived from a conventional MOS transistor, which is a main element of an MOS or CMOS process, the diode “inherits” the properties of the MOS transistor, whose process engineering is well known. In particular, critical pn junctions to the substrate and the regions of the gate oxide near the surface fortunately do not differ from those of known MOS transistors.

Diffusion or implantation regions over the gate electrode may be produced in a self-adjusting manner. In MOS and CMOS processes, production of the gate oxide and of the gate electrode is subject to stringent process control. In this way, ESD diodes with well defined lateral dimensions can be produced, since dimensional deviations would be detected within the framework of the continuous MOS parameter measurements. Other potential problems of the diode, such as for example leakage currents, surface charges, impurities, etc. would affect the MOS transistors of the integrated circuit in the same measure, and as a result would be detected with standard process control techniques. Consequently, the ESD diodes require no additional measurements on the wafer.

The gate electrode is short-circuited with the electrode that contacts the deliberately wrongly doped region. Accordingly, it can be assured that undesirable surface effects and the resulting leakage currents are essentially avoided.

In one embodiment the ESD structure is embedded in its own well, and the appropriate conductivity types are matched to it. Therefore, the embedded ESD structure is insulated from the substrate.

One region of the ESD diode, typically the anode region, may be completely surrounded by the region that forms the cathode to provide increased latch-up protection.

The integrated circuit and the ESD diode are preferably produced in MOS or CMOS process technology, and a gate dielectric that includes silicon dioxide is present and separates the semiconductor body from the gate electrode. The gate electrode is may be designed as a polysilicon gate. The invention may be applied to other process technologies (i.e., the gate electrode and the gate oxide may include other materials). It is contemplated that ESD diodes without gate oxide may also be used.

Advantageously, the ESD diode is easily manufactured since additional process steps are not required (e.g., implantation to produce an ESD Zener diode or the production of a buried layer or an epitaxial layer is not required). As a result, the ESD diode may be economically produced.

These and other objects, features and advantages of the present invention will become more apparent in light of the following detailed description of preferred embodiments thereof, as illustrated in the accompanying drawings.

### BRIEF DESCRIPTION OF THE DRAWING

FIG. 1 illustrates a circuit arrangement with an inventive ESD diode;

FIG. 2 illustrates a partial section of a first embodiment of an inventively integrated ESD diode;

FIG. 3 illustrates a partial section of a second embodiment of an inventive integrated ESD diode; and

FIG. 4 illustrates a partial section of a third embodiment of an inventive integrated ESD diode.

### DETAILED DESCRIPTION OF THE INVENTION

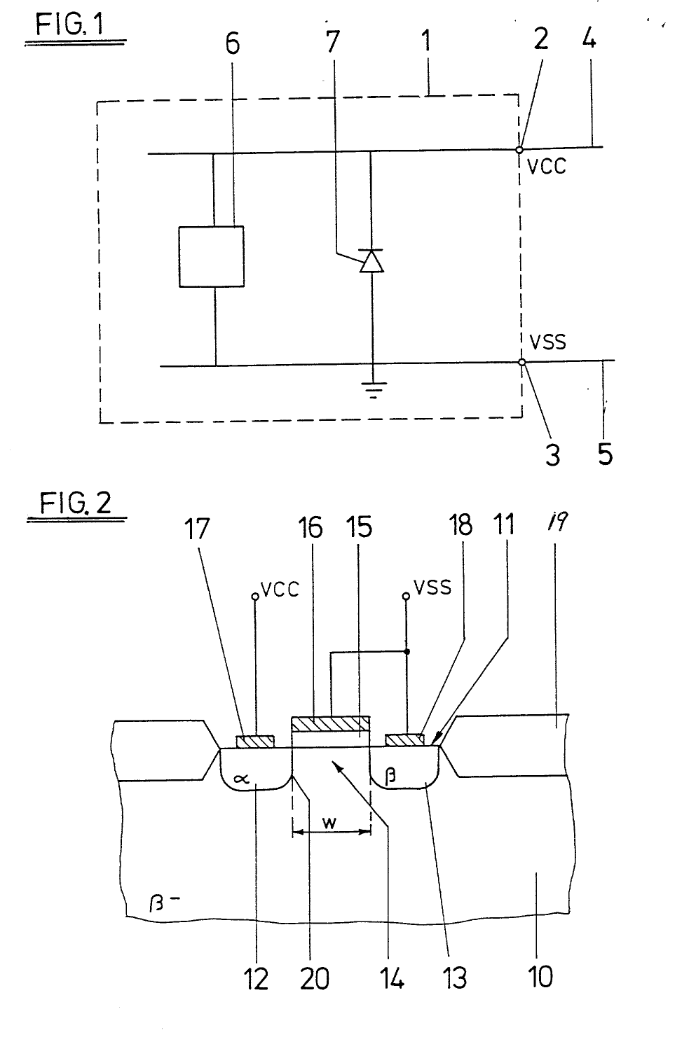

FIG. 1 illustrates an integrated circuit 1. The integrated circuit 1 is connected via supply voltage inputs 2, 3, to a first voltage bus 4 with a first supply voltage VCC and to a second voltage bus 5 with a second supply voltage VSS, respectively. In the present example VSS is reference ground.

The integrated circuit 1 includes a circuit 6 that is being protected (e.g., a logic circuit, a program-controlled unit, a semiconductor memory, a power circuit, etc.). The integrated circuit 1 also includes an ESD protective element 7 to protect the circuit 6. The circuit 6 that is being protected and the ESD protective element 7 are connected between the voltage buses 4, 5.

FIG. 2 illustrates a partial section of a first embodiment of an inventive integrated ESD diode. A semiconductor body 10 includes a weakly-doped silicon substrate. The semiconductor body 10 has a wafer front side 11 within which are embedded a first, a 5 doped region 12 and a second, ,-doped region 13. The regions 12, 13 are spaced apart from one another by a spacing distance W that defines a drift region 14. The drift region 14 includes the background doping (i.e., the doping of the semiconductor body 10). The first region 12 forms a cathode and the second region 13 together with the drift region 14 form an anode of the ESD diode. The second region 13 has a higher doping concentration than the drift region 14. Electrodes 17, 18 are attached to the surface 11 in the first region 12 and the second region 13, respectively. The electrode 17 is connected to VCC, while the electrode 18 is connected to VSS.

A gate oxide 15 is disposed over the drift region 14, and a gate electrode 16 is disposed on the gate oxide 15. The gate oxide 15 may include silicon dioxide, and the gate electrode 16 may include polysilicon. The gate electrode 16 is electrically connected to the electrode 18 of the second region 13, and thus to the second supply potential VSS.

The ESD diode 7 is established through the regions of the elements 12-16. The regions outside the ESD diode 7 adjoining the surface 11 are covered by a field oxide 19 that laterally passivates the semiconductor body 10. Furthermore, the entire ESD diode 7 may be covered by a passivation (not shown). The function of the inventive lateral ESD diode 7 shall now be explained in more detail below.

A parasitic noise signal may arise on the semiconductor chip through a potential bus 2, 3, for example during transport or during handling, or also through a fluctuation in the supply voltage. If a parasitic noise signal is coupled into the integrated circuit 1, and the signal exceeds the breakdown voltage of the ESD diode 7, then the space charge zone at pn junction 20 between the first zone 12 and the drift zone 14 breaks down. This results in a current path from the first potential bus 4, via the first zone 12, the drift zone 14, and the second zone 13, to the second potential bus 5. The ESD diode 7 thus protects the integrated circuit 1 from a parasitic overvoltage by draining this voltage off to the potential busses 5, so the overvoltage does not damage the integrated circuit.

Significantly, undesirable surfaces are eliminated (e.g., parasitic surface charges and surface leakage currents resulting therefrom), since the gate electrode 16 is disposed above the drift zone 14 and is connected to the second supply potential VSS. This increases the reliability of the ESD diode.

Under normal operating conditions the ESD protective element(s) must not impair the function of the integrated semiconductor circuit 1. Consequently, the breakdown voltage of the ESD diode 7 must be located within a voltage range whose lower limit is the maximum signal voltage coupled into the integrated circuit 1, and whose upper limit is characterized by the minimum breakdown voltage of the integrated circuit 1. The breakdown voltage of the ESD diode 7 is adjusted/set, so that despite process variations in the production of the integrated circuit 1 and the ESD diode 7, the system still functions properly.

The breakdown voltage of the ESD diode 7 can be adjusted through the doping concentrations in the zones 12, 13, and 14. However, there is an important boundary condition in the production of ESD protective structures, in that the process management should not be changed through the insertion of the ESD protective structures, of course if at all possible. Thus, the doping concentrations and/or the thickness of the gate oxide 15 should not be changed, if possible.

The layouts of customary lateral MOSFETs that are also used for the corresponding MOS or CMOS circuit are preferably used as the ESD elements. However, in the layout of these MOSFETs, the conductivity type of the source region or of the drain region is exchanged. The pn diode 7 as ESD protection is thus produced by a relatively simple technique, and it is produced in MOS or CMOS technology. Using the MOS or CMOS technology of the protected circuit 6 assures that the process parameters of the ESD diode 7 likewise are easily controlled and adjusted.

A conventional field oxide, for example produced in LOCOS technology, or also any other masking (e.g., a photoresist) can be used as a doping mask. It is preferred that the gate oxide 15 is applied first, and then the gate electrode 16 is applied on the gate oxide 15. Then, using the gate electrode 16 as a mask, the first zone 12 and the second zone 13 are attached to the semiconductor body 10.

Using the above doping mask, the doping atoms for the a-doping of the first zone 12 and the P-doping for the second zone 13 are introduced into the semiconductor 1 by a diffusion process, preferably in two separate process steps. When diffusing, the doping atoms distribute themselves laterally and vertically homogeneously over the corresponding regions 12, 13. However, it is also conceivable to introduce the doping atoms into the semiconductor bodies 1 by ion implantation. Ion implantation introduces an accurately measurable dopant dose into the semiconductor body 1, to provide the switching threshold of the ESD diode. However, ion implantation must be followed by a suitable temperature step so the dopant atoms are electrically activated and crystal damage created by the ion bombardment is healed. Whether ion implantation or diffusion is used to produce the regions 12, 13 typically follows from the particular process that is utilized to manufacture the integrated circuit 1.

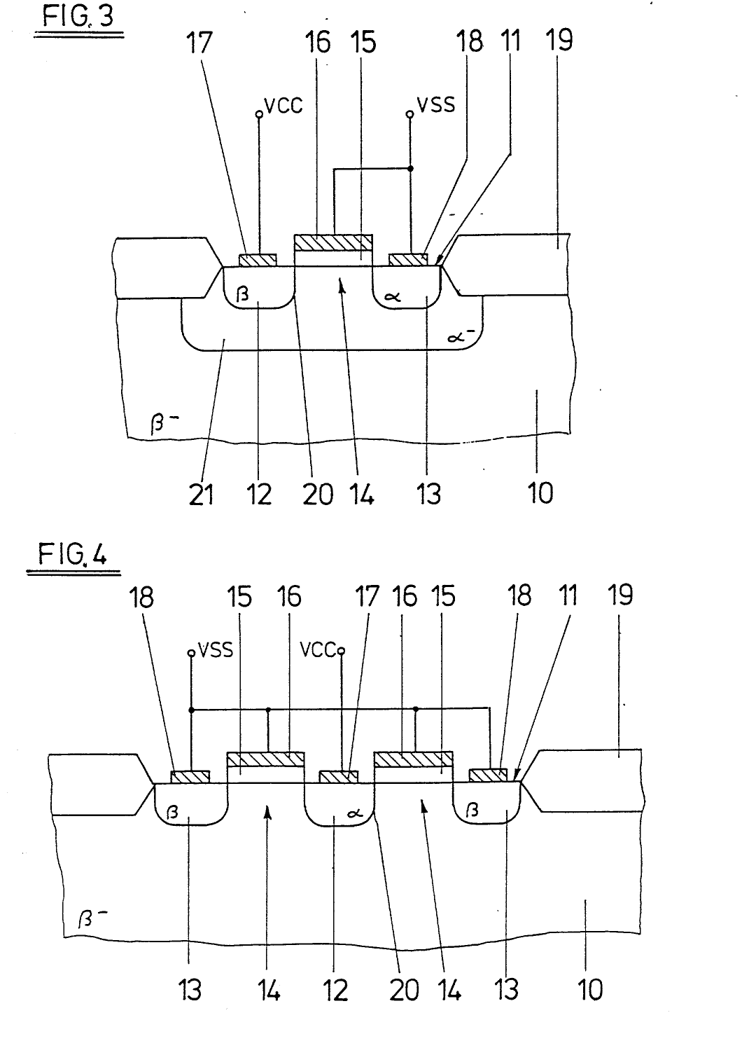

FIG. 3 illustrates a partial section through a second embodiment of an ESD diode. A weakly α-doped well 21 is inserted into the semiconductor body 10, for example by diffusion. The mutually spaced zones 12, 13 are embedded in this well 21. In contrast to the embodiment illustrated in FIG. 2, in the embodiment of FIG. 3 the conductivity types of the first zone 12 and of the second zone 13 are exchanged (i.e., the first zone 12 is now P-doped and the second zone 13 is a-doped). This establishes the ESD diode 7 embedded in the well 21 and electrically insulated from the substrate of the semiconductor body 10.

FIG. 4 illustrates a third embodiment of the ESD diode 7, corresponding to FIG. 2, in which the first zone 12 is laterally enclosed by the second zone 13. In this way, the substrate all around the ESD diode 7 is maintained at a defined potential to provide improved latch-up protection.

The ESD structure can have a circular, annular, square, serpentine, finger-shaped, fanned-out, or similar layout.

In the present embodiment a laterally shaped ESD diode 7 has been described. However, it is contemplated that a vertically formed ESD diode 7 may also be used, although this would be more complicated. Vertically designed ESD structures, using an epitaxial layer and/or a buried layer may be used especially for integrated semiconductor circuits 1 that are designed in trench technology.

Possible new embodiments naturally can be created from all the embodiments of FIGS. 2-4 by interchanging the a and P conductivity types.

The ESD diodes are especially suitable for MOS/CMOS-integrated circuits, which require protection of the supply voltage networks against ESD overvoltages. This includes integrated circuits with analog functions and having their own analog supply voltage, especially analog circuits that operate with a high operating voltage and thus practically have no inherent protection. The invention is also suited for digital integrated semiconductor circuits with a high-voltage supply network.

Although the present invention has been shown and described with respect to several preferred embodiments thereof, various changes, omissions and additions to the form and detail thereof, may be made therein, without departing from the spirit and scope of the invention.

What is claimed is:

1. An electrostatic discharge (ESD) protective structure that protects an integrated semiconductor circuit connected between a first potential bus with a first supply potential (VCC) and a second potential bus with a second supply potential (VSS), said electrostatic discharge protective structure comprising:
a laterally formed electrostatic discharge diode having a first region doped with a first conduction type and a second region, spaced apart from said first region;
a doped second conduction type, wherein said electrostatic discharge protective structure is located between the first and second potential busses and drains off an overvoltage pulse to one of the first and second potential busses, wherein said laterally formed electrostatic discharge diode includes a gate electrode located between said first region and said second region corresponding to the width (W) or the length of the gate electrode.

2. The electrostatic discharge protective structure of claim 1, wherein said protective structure includes a semiconductor body having a surface in which said first region and said second region are embedded, wherein said first region is connected via a first electrode to the first potential bus, and said second region is connected via a second electrode to the second potential bus.

3. The electrostatic discharge protective structure of claim 2, wherein said semiconductor body includes charge carriers of the second conduction type, and said gate electrode and said second electrode are connected to said second potential bus.

4. The electrostatic discharge protective structure of claim 2, wherein said semiconductor body includes charge carriers of the first conduction type, and at least one well of the second conduction type is embedded in said semiconductor body, and said first and second regions are embedded in said well.

5. The electrostatic discharge protective structure of claim 4, wherein said second regions laterally enclose said first regions.

6. The electrostatic discharge protective structure of claim 4, wherein the integrated semiconductor circuit is configured and arranged as an MOS or CMOS circuit.

7. The electrostatic discharge protective structure of claim 2, comprising a gate dielectric that spaces said semiconductor body at a distance from the gate electrode.

8. The electrostatic discharge protective structure of claim 7, wherein said gate dielectric contains silicon dioxide and said gate electrode contains polysilicon.

9. A method for producing an electrostatic discharge protective structure that is co-integrated into an integrated circuit with a circuit to be protected, and the electrostatic discharge protective circuit and the circuit to be protected are disposed electrically in parallel between first and second voltage busses, said method comprising:
inserting doping atoms of a first conduction type for the first region;
inserting doping atoms of a second conduction type for the second region;
applying a gate dielectric to the first surface over an enrichment region that is located between the first region and the second region;
applying a metallization or a polysilicon layer respectively to the first and second regions and to the gate dielectric.

10. The method of claim 9, wherein said gate dielectric and said gate electrode are produced first, and then said first and the second regions are inserted in a self-adjusting manner into the semiconductor body using the gate dielectric as a mask.

11. The method of claim 10, wherein said step of inserting doping atoms of a first conduction type for the first region includes the step of ion implantation of the doping atoms into the first region.

12. The method of claim 10, wherein said integrated semiconductor circuit and said electrostatic diode are produced in MOS/CMOS technology.

13. An integrated circuit with electrostatic discharge protection, said integrated circuit comprising:
a circuit to be protected;
an electrostatic discharge device that is disposed electrically parallel to said circuit to be protected between first and second voltage busses, wherein said electrostatic discharge device includes a laterally shaped electrostatic discharge diode having:
(i) a first region doped with a first conduction type material within a substrate;
(ii) a second region doped with a second conduction type material within said substrate; and
(iii) a gate electrode having a width W and located between said first and second regions such that said first and second regions are separated by the width W.

14. The integrated circuit of claim 13, comprising a gate oxide disposed on said substrate between said first and second conduction regions and underlying said gate electrode.

15. The integrated circuit of claim 14, comprising a first electrode disposed on said substrate overlaying said first region, and a second electrode disposed on said substrate overlaying said second region, wherein said first electrode is connected to the first voltage bus and said second electrode is connected to said second bus.
